(19) United States
(12) Patent Application Publication
(10) Pub. No.: US 2019/0259736 A1
(43) Pub. Date: Aug. 22, 2019

(54) Surface-Mounted RGB-LED Packaging Module and Preparing Method Thereof

(71) Applicant: SHANDONG PROSPEROUS STAR OPTOELECTRONICS CO., LTD., Tai'an, Shandong (CN)

(72) Inventors: Shaoli Li, Tai'an, Shandong (CN); Yiping Kong, Tai'an, Shandong (CN); Xincheng Yuan, Tai'an, Shandong (CN)

(21) Appl. No.: 16/346,118

(22) PCT Filed: Jun. 21, 2017
(86) PCT No.: PCT/CN2017/089336

§ 371 Date: Apr. 30, 2019

(30) Foreign Application Priority Data
Mar. 28, 2017 (CN) 201710194308.8

(51) Int. Cl. H01L 25/075; H01L 33/44; H01L 33/62; H01L 25/00

(52) U.S. Cl. CPC H01L 25/0753; H01L 33/44; H01L 2933/0033; H01L 25/50; H01L 2933/0066; H01L 33/62

(57) ABSTRACT

The present invention provides a surface-mounted RGB-LED packaging module and a preparing method thereof, a protective layer is arranged on the light emitting units, the number of the light emitting units is at least two, each light emitting unit includes four mutually independent upper pads and a group of RGB LED chips, the RGB LED chips are arranged on any one of the upper pads and connected with the other three upper pads by keys and wires, each upper pad is provided with a metal hole that penetrates the substrate and is conductive up and down, lower pads are arranged on the reverse side of the substrate corresponding to the metal holes, and the lower pads are independent from each other, so the production efficiency of LEDs in subsequent production and application is greatly improved, and the production cost is greatly reduced.

### TECHNICAL FIELD

The present invention relates to an SMD LED packaging technology, and more particularly relates to a surface-mounted RGB LED packaging module and a preparing method thereof.

### BACKGROUND ART

With continuous development of the display screen industry, LEDs for display screens are rapidly transformed from original DIP (dual inline-pin package) structures to SMD (Surface Mounted Devices) structures. The LEDs of the SMD structures have been increasingly accepted by users due to the advantages of light weight, smaller size, automatic installation, large illumination angle, uniform color, little attenuation and the like. Although the general SMD LEDs have the above advantages, problems of large attenuation, long heat conduction path, low carrying current, complicated production, low reliability, low moisture resistance, poor weather resistance and the like still exist. If the reliability of a product is to be improved without changing the overall structure of the product, there is still no good solution in the industry.

In the conventional SMD LED preparing, the products are generally of PLCC4 structures (e.g., 3528, 2121, 1010, and other specifications). However, these structures exist individually at present. When customers use the products, the production efficiency is low, the products can only be mounted one by one, and the maintenance difficulty is high. When small-sized products are produced, e.g., when the products having the specifications of 1.0 mm*1.0 mm or less are produced, the production difficulty of the products is multiplied, the mechanical strength of the products is very low, the products are easily damaged by external force, the production efficiency is also very low, and the requirements for mounting equipment are high. For the single-mount problem, the production efficiency is improved to certain extent by using a COB (chip on board) integrated module. However, the COB integrated module also causes many problems, such as color development difference and poor entire screen consistency caused by center value differences of different batches of chips or substrate ink differences. On the other hand, the chip directly mounted on the circuit board is not well protected such that the reliability cannot be guaranteed, and the failure maintenance cost of the light emitting unit is high. Due to the problems of color development difference and poor entire screen consistency caused by center value differences of different batches of chips or substrate ink differences, high failure maintenance cost of the light emitting unit and the like, the prior art has yet to be improved and developed.

### SUMMARY OF THE INVENTION

The present invention is directed to provide a surface-mounted RGB LED packaging module and a preparing method thereof, aiming at solving the problems of low production efficiency, high production difficulty, low product mechanical strength and the like of the existing mounted RGB LED products.

To solve the above problems, the technical scheme of the present invention is as follows:

A surface-mounted RGB LED packaging module, comprising a substrate and light emitting units arranged on the substrate; a protective layer is arranged on the light emitting units, the number of the light emitting units is at least two, and each light emitting unit comprises four mutually independent upper pads and a group of RGB LED chips; the RGB LED chips are arranged on any one of the upper pads and connected with the other three upper pads by keys and wires; each upper pad is provided with a metal hole that penetrates the substrate and is conductive up and down; lower pads are arranged on the reverse side of the substrate corresponding to the metal holes, and the lower pads are independent from each other.

The surface-mounted RGB LED packaging module, wherein an isolating frame is further arranged around the light emitting units.

The surface-mounted RGB LED packaging module, wherein the isolating frame is a lighttight black frame.

The surface-mounted RGB LED packaging module, wherein the surface of the protective layer is rough and non-reflective.

A method for preparing the surface-mounted RGB LED packaging module, comprising the following steps:

step 1: cladding two sides of a substrate with copper, drilling holes, and forming multiple groups of metal holes penetrating up and down to conduct the front and reverse sides of the substrate;

step 2: etching multiple groups of upper pads on the front side of the substrate, etching lower pads on the reverse side, and etching electroplating circuits to electrically connect all the upper pads with the lower pads on the substrate;

step 3: electroplating the substrate;

step 4: die-bonding RGB LED chips onto the substrate, and welding wires to form a plurality of light emitting units; and

step 5: cutting the substrate according to the number of the light emitting units as needed to form packaging modules having a plurality of light emitting units and cutting off the electroplating circuits during cutting so that all the upper pads and the lower pads are independent from each other.

The method for preparing the surface-mounted RGB LED packaging module, wherein the electroplating circuits are arranged on the front side and/or the reverse side of the substrate.

The method for preparing the surface-mounted RGB LED packaging module, wherein step 4 further comprises: after the light emitting units are formed, preparing a protective layer on the light emitting units.

The method for preparing the surface-mounted RGB LED packaging module, wherein step 4 further comprises: after the light emitting units are formed, preparing an isolating frame around each of the light emitting units.

The method for preparing the surface-mounted RGB LED packaging module, wherein the isolating frame is baked at a temperature of 100-300 degrees Celsius for aging.

The method for preparing the surface-mounted RGB LED packaging module, wherein step 3 further comprises filling and sealing the metal holes.

The surface-mounted RGB LED packaging module and the preparing method thereof according to the present invention have the beneficial effects that a plurality of light emitting units is integrated into one packaging module, so that the production efficiency of LEDs in subsequent production and application is greatly improved, and the production cost is greatly reduced; at the same time, the plurality of light emitting units is integrated into one module, so compared with the conventional single LED, the LED module provided by the present invention has better sealing performance, and is less susceptible to the erosion of water vapor and longer in service life; in addition, the plurality of light emitting units is integrated on one module, which can effectively improve the overall resistance of a display screen to external mechanical strength; and the isolating frame is arranged around the light emitting units to reduce the influence among the light emitting units, thereby improving the resolution and contrast of the LED display screen. Compared with the existing integrated module, the integration of a plurality of light emitting units to one module has the advantages that one template of the present invention includes fewer light emitting units, which can effectively avoid the problems of color development difference and poor entire screen consistency caused by center value differences of different batches of chips or substrate ink differences; in addition, the existing integrated module is high in maintenance cost if some light emitting units fail, but the present invention is low in maintenance cost.

### BRIEF DESCRIPTION OF THE DRAWINGS

FIG. 1 is a structure diagram of an existing PPA support.

FIG. 2 is a structure diagram of an existing CHIP type packaging support.

FIG. 3 is a front view of a 1*2 surface-mounted RGB LED packaging module according to the present invention.

FIG. 4 is a front view of a 1*2 surface-mounted RGB LED packaging module with an isolating frame according to the present invention.

FIG. 5 is a reverse view of the 1*2 surface-mounted RGB LED packaging module according to the present invention.

FIG. 6 is a cross-sectional view of the 1*2 surface-mounted RGB LED packaging module according to the present invention.

FIG. 7 is a cross-sectional view of the 1*2 surface-mounted RGB LED packaging module with an isolating frame according to the present invention.

FIG. 8a is an electroplating circuit diagram of the 1*2 surface-mounted RGB LED packaging module according to the present invention.

FIG. 8b is a cutting circuit diagram of the 1*2 surface-mounted RGB LED packaging module according to the present invention.

FIG. 9 is a front view of a 1*3 surface-mounted RGB LED packaging module according to the present invention.

FIG. 10 is a reverse view of the 1*3 surface-mounted RGB LED packaging module according to the present invention.

FIG. 11a is an electroplating circuit diagram of the 1*3 surface-mounted RGB LED packaging module according to the present invention.

FIG. 11b is a cutting circuit diagram of the 1*3 surface-mounted RGB LED packaging module according to the present invention.

FIG. 12 is a front view of a 1*3 surface-mounted RGB LED packaging module according to the present invention.

FIG. 13 is a reverse view of the 1*3 surface-mounted RGB LED packaging module according to the present invention.

FIG. 14 is a cutting circuit diagram of the 1*3 surface-mounted RGB LED packaging module according to the present invention.

FIG. 15 is a front view of a 1*4 surface-mounted RGB LED packaging module according to the present invention.

FIG. 16 is a reverse view of the 1*4 surface-mounted RGB LED packaging module according to the present invention.

FIG. 17a is a reverse electroplating circuit diagram of the 1*4 surface-mounted RGB LED packaging module according to the present invention.

FIG. 17b is a reverse cutting circuit diagram of the 1*4 surface-mounted RGB LED packaging module according to the present invention.

FIG. 18a is a front electroplating circuit diagram of the 1*4 surface-mounted RGB LED packaging module according to the present invention.

FIG. 18b is a front cutting circuit diagram of the 1*4 surface-mounted RGB LED packaging module according to the present invention.

FIG. 19 is a reverse electroplating circuit diagram of the 1*4 surface-mounted RGB LED packaging module according to the present invention.

FIG. 20 is a reverse electroplating circuit diagram of the 1*4 surface-mounted RGB LED packaging module according to the present invention.

FIG. 21 is a preparing flow diagram of a surface-mounted RGB LED packaging module according to the present invention.

Indication for drawing reference: 1. substrate; 101. identification zone; 2. upper pad; 201. first weld zone; 202. second weld zone; 203. chip weld zone; 204. third weld zone; 3. metal hole; 4. RGB LED chip; 401. key and wire; 5. lower pad; 6. electroplating circuit; 7. cutting line; 8. protective layer; 9. isolating frame.

### DETAILED DESCRIPTION OF THE INVENTION

For the purpose of making objectives, technical schemes and advantages of the present invention clearer, the following further describes the present invention in detail with reference to the accompanying drawings and embodiments.

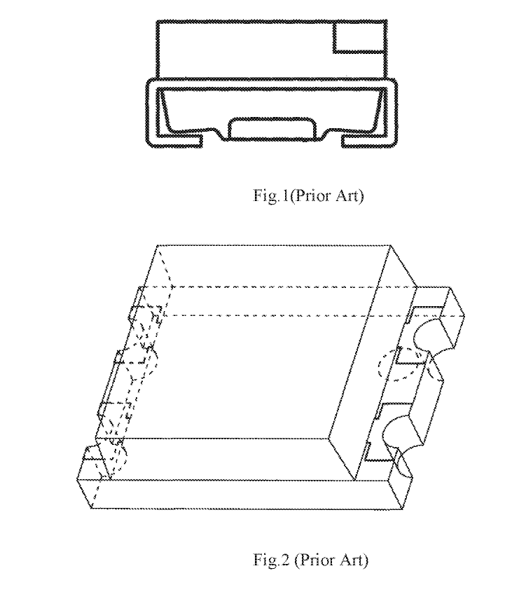

FIG. 1 is a structure diagram of an existing PPA+ copper pin packaging support, FIG. 2 is a structure diagram of an existing CHIP type packaging support, and both are of single packaging structures. In actual production, with the reduction of pixel pitches of LED display screens, more and more packaging devices are on per unit area, so the number of LED packaging devices used is huge in actual use, so the production efficiency is extremely low by the single-mount production method.

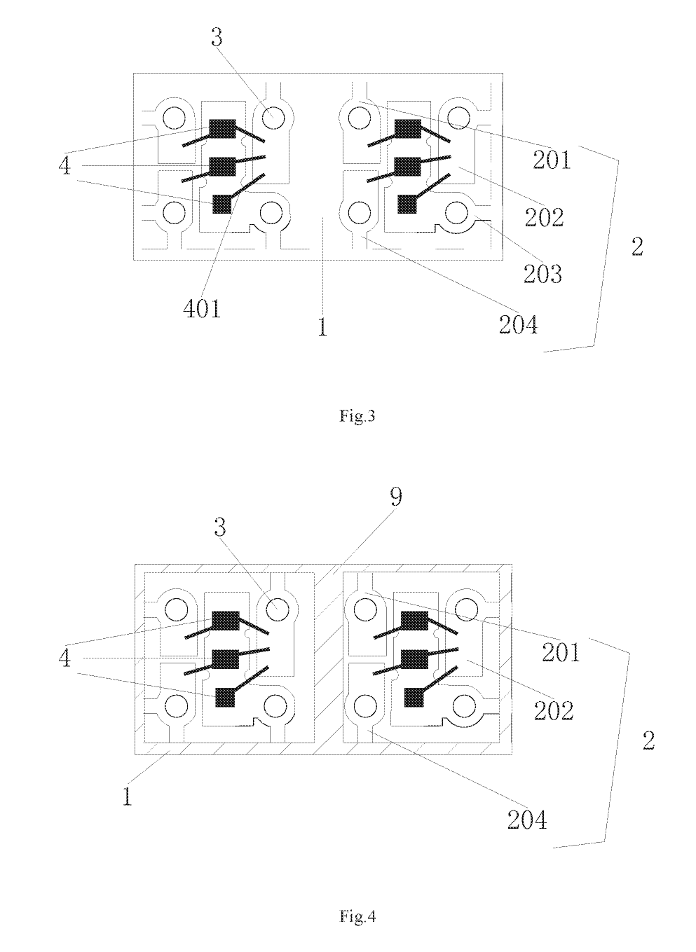

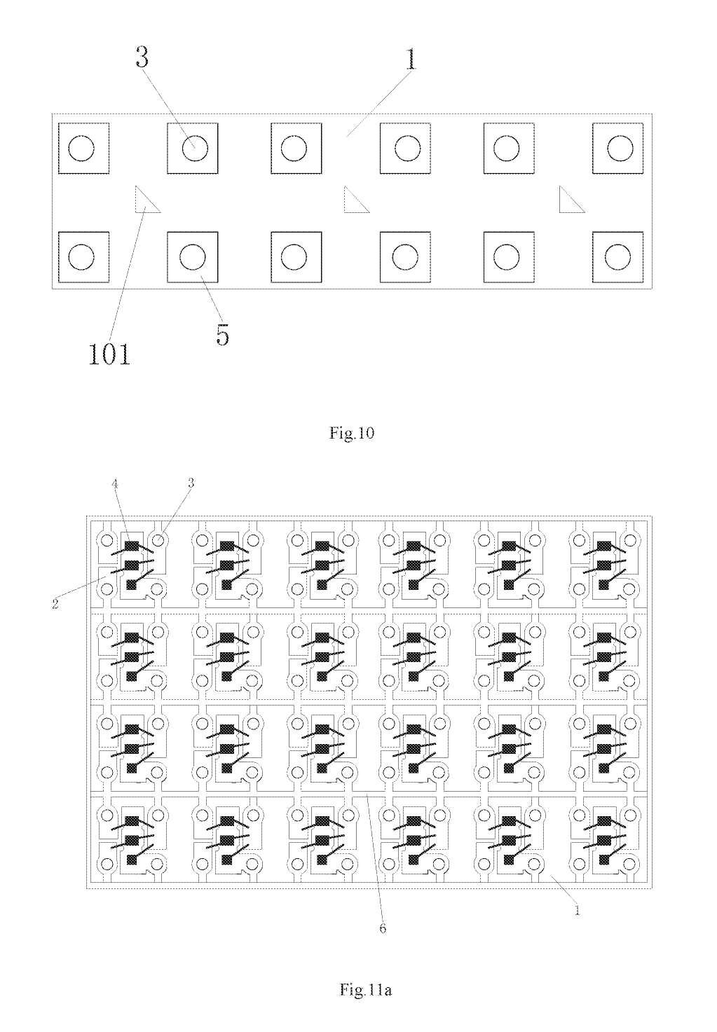

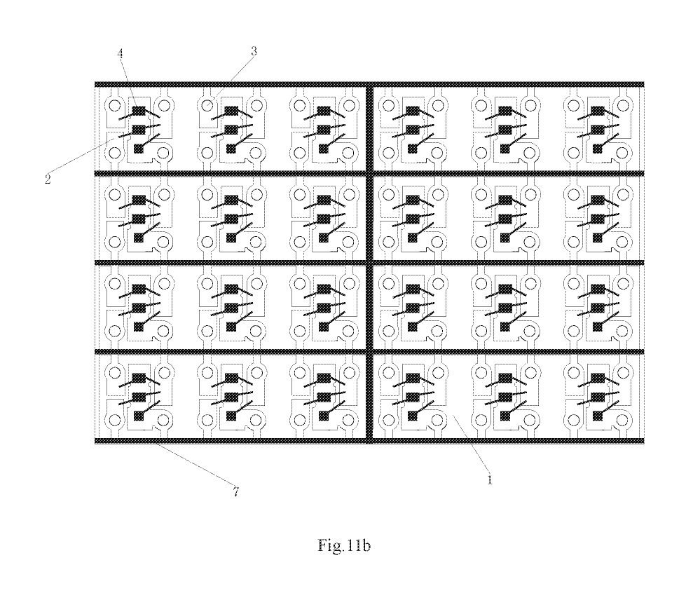

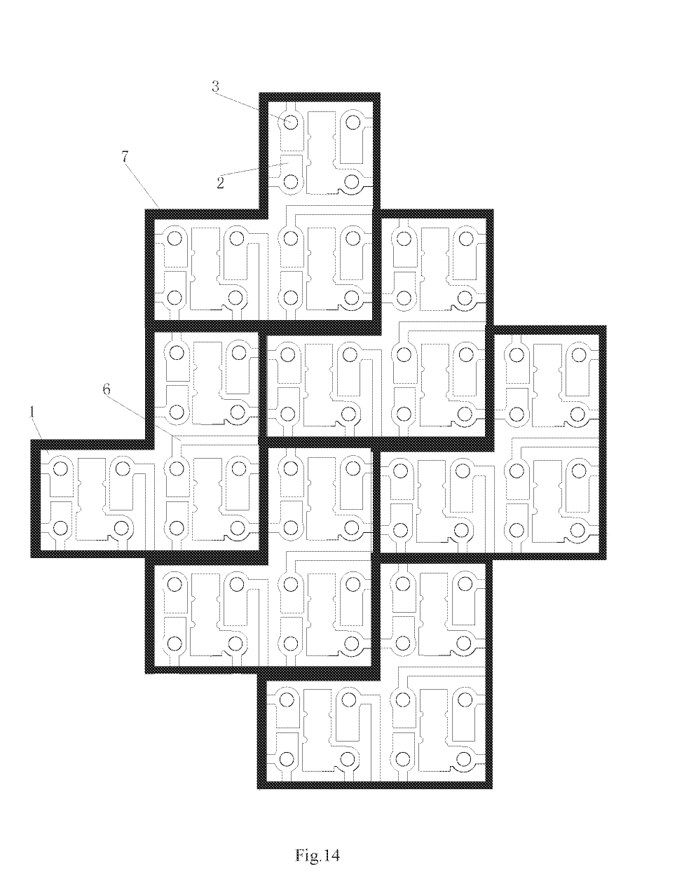

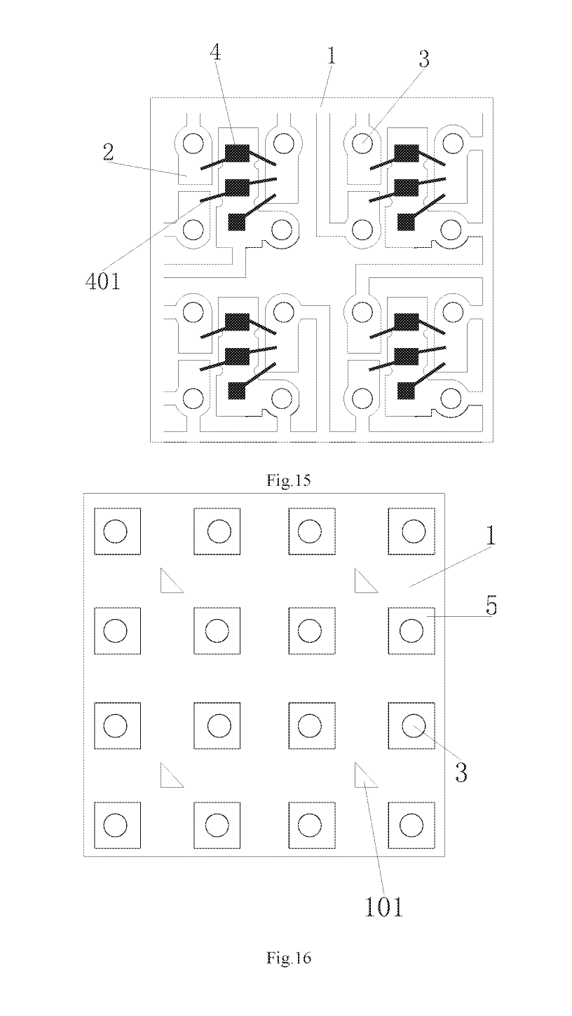

Referring to FIG. 3 to FIG. 20, embodiments of a surface-mounted RGB LED packaging module according to the present invention are provided. The surface-mounted RGB LED packaging module provided by the present invention includes a substrate 1 and light emitting units arranged on the substrate 1, a protective layer 8 is arranged on the light emitting units, the number of the light emitting units is at least two, each light emitting unit includes four mutually independent upper pads 2 and a group of RGB LED chips 4, the RGB LED chips 4 are arranged on any one of the upper pads 2 and connected with the other three upper pads 2 by keys and wires 401, each upper pad 2 is provided with metal holes 3 that penetrates the substrate 1 and is conductive up and down, lower pads 5 are arranged on the reverse side of the substrate 1 corresponding to the metal holes 3, and the lower pads 5 are independent from each other. Compared with the conventional single LED package, the packaging module according to the present invention includes a plurality of light emitting units arranged on the substrate 1, and LED beads are mounted later in the form of a module, so the mounting efficiency of the present invention is extremely high compared with the single mounting method, and the mounting efficiency is improved as the number of the light emitting units on the packaging module increases. If the number of the light emitting units on the packaging module is 16, the mounting efficiency can be increased by 16 times. Preferably, the number of the light emitting units of the present invention is 2-16. The light emitting units may also be arranged in an inverted “L” shape. The arrangement of the light emitting units is not limited in the present invention and may be a transverse-shape “-” arrangement, or a combination of rows and columns of M×N (M and N are integers), or other irregular arrangement, and the present invention is not limited thereto. It should be noted that modifications or changes could be made by those of ordinary skill in the art according to the above description, and all these modifications and changes shall fall within the scope of the appended claims of the present invention.

In a practical application, isolating frames 9 are arranged around the light emitting units to reduce the influence among the light emitting units, thereby improving the resolution and contrast of an LED display screen. Preferably, the isolating frames 9 are lighttight frames, which further prevent light from penetrating the isolating frames 9. Further, the isolating frames 9 are black.

In a practical application, the surface of the protective layer 8 is rough and non-reflective. Preferably, the protective layer 8 is a translucent epoxy resin glue layer with a diffusing agent. The arrangement of the protective layer 8 is capable of preventing the ingress of water vapor and preventing mechanical damage of components. The translucent epoxy resin glue with the diffusing agent is used as the protective layer 8 in the present invention, so that light penetrates the protective layer 8 more uniformly, and the influence of the protective layer 8 on the light is reduced.

In a practical application, as shown in FIG. 3, the four independent upper pads are respectively an “L”-shaped chip weld zone 203 in the middle for holding the RGB LED chips 4, as well as a first weld zone 201, a second weld zone 202 and a third weld zone 203 at the upper left corner, the upper right corner and the lower left corner respectively. Preferably, the second weld zone 203 serves as a common pole zone. The RGB LED chips 4 are fixed on the chip weld zone 203 in the center by means of die-bonding glue, so that the light can be more concentrated.

In actual production, both the upper pads 2 and the lower pads 5 are welded after electroplating. Since the upper pads 2 and the lower pads 5 are independent from each other, all the upper pads 2 and the lower pads 5 need to be electrically connected before electroplating. Electroplating circuits are provided in the present invention to connect all the pads. When it is cut into single products, the electroplating circuits are cut off to keep the respective pads independent. However, the package provided by the present invention is not a single package but is a packaging module including a plurality of light emitting units. Thus, when the electroplating circuits are provided, all the pads are not simply connected. When the products are cut, it is necessary to cut off all the electroplating circuits while the packaging modules having a plurality of light emitting units are cut.

The following specifically describes the present invention in conjunction with several embodiments of the present invention:

### Embodiment 1

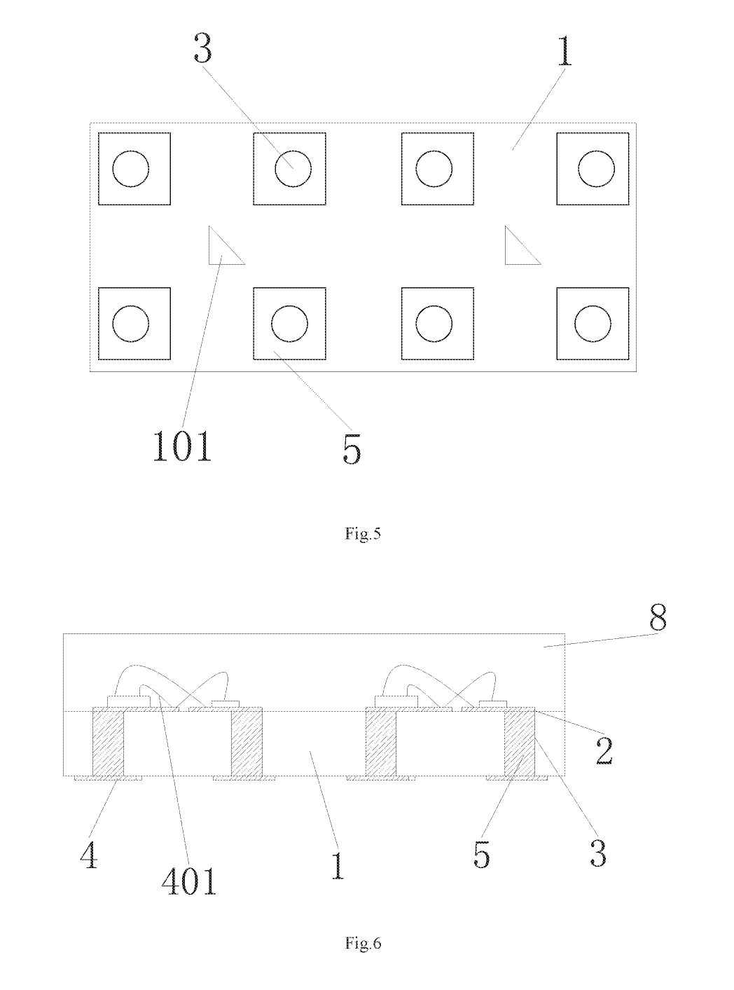

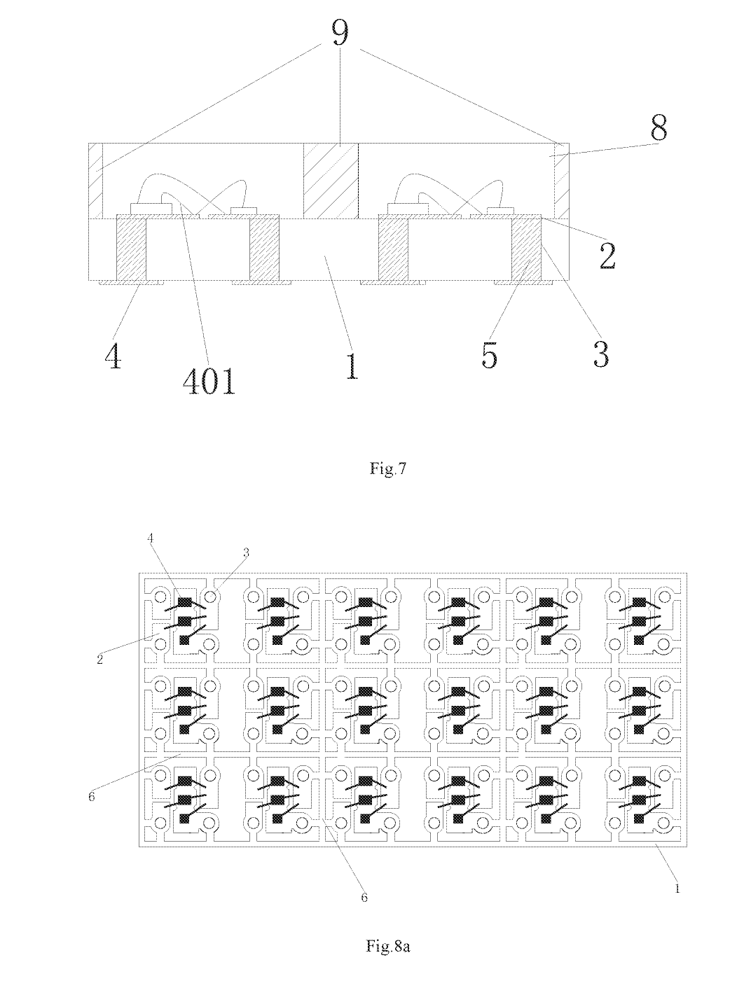

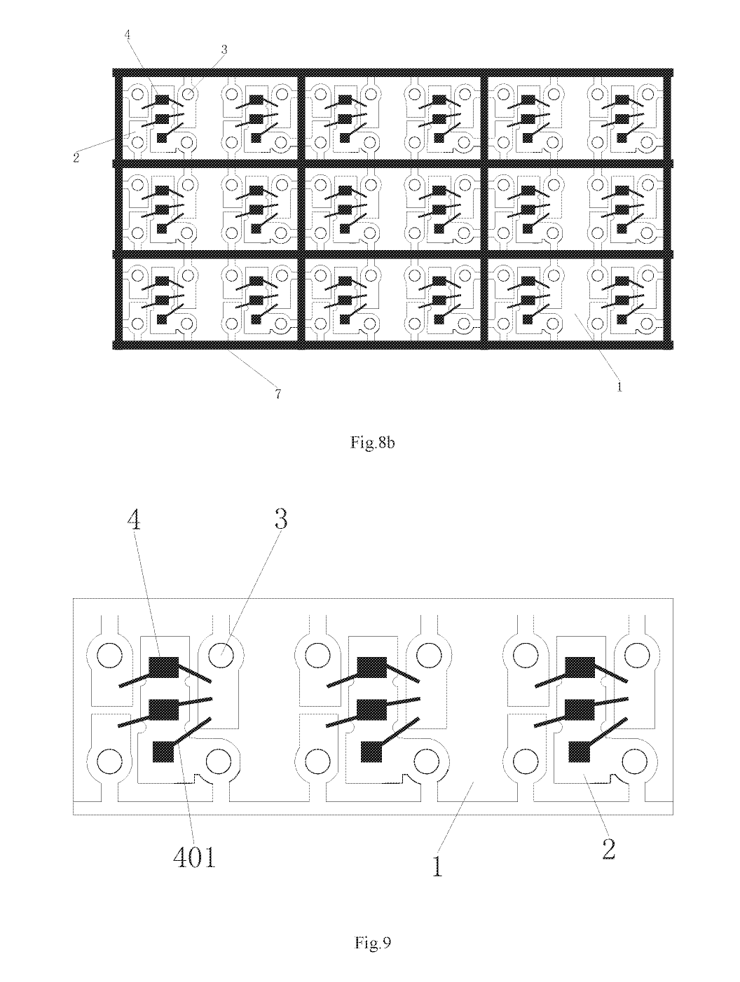

Referring to FIGS. 3-8b, a 1*2 surface-mounted RGB LED packaging module according to the present invention is provided. The packaging module has two light emitting units. In actual production, as shown in FIG. 4 and FIG. 7, isolating frames 9 are arranged around the light emitting units to reduce the influence between the light emitting units. Preferably, as shown in FIG. 5, on the reverse side of the substrate 1, identification zones 101 are arranged in the middle of each light emitting unit to facilitate subsequent test and help a packaging apparatus identify the front and reverse sides of the packaging module. As shown in FIG. 6 and FIG. 7, a protective layer 8 is arranged on the light emitting units. The protective layer 8 is preferably a translucent epoxy resin glue layer with a diffusing agent. The arrangement of the protective layer 8 is capable of preventing the ingress of water vapor and preventing mechanical damage of components. Preferably, the protective layer 8 is formed by die pressing or glue injection. Referring to FIG. 8a and FIG. 8b, in actual production, a plurality of light emitting units is first arranged on the substrate 1, and then packaging modules having a specified number of lights emitting units are cut. FIG. 8a is an electroplating circuit diagram of packaging modules having two light emitting units, and FIG. 8b is a corresponding cutting circuit diagram. The cutting process is performed along cutting lines 7. In a practical application, the cutting lines 7 do not need to be actually draw, only a program is set, and the cutting apparatus performs cutting according to the set cutting direction. In actual production, the blade edge of the cutting tool is wider than electroplating circuits 6 to ensure that the electroplating circuits 6 can be completely cut off. The electroplating circuits 6 may be arranged on the front side of the substrate 1, or on the reverse side of the substrate 1, or on the front and reverse sides of the substrate 1. In the presence of the metal holes 3, the upper pads 2 and the lower pads 5 at the corresponding positions are mutually conductive, so all the pads can be electrically connected as long as all the upper pads 2 or all the lower pads 5 are connected. As shown in FIGS. 8a and 8b, in the present embodiment, the electroplating circuits 6 are arranged on the front side of the substrate 1, buses of the electroplating circuits 6 are arranged on the cutting lines 7, and all the upper pads 2 are connected to the buses of the nearest electroplating circuits 6 through the electroplating circuits 6 to ensure that all the electroplating circuits 6 can be cut off during the cutting process, and all the upper pads 2 are independent from each other. The electroplating circuits 6 in FIG. 8a are only one of the circuit connection modes, those skilled in the art can easily conceive of other connection modes according to the present invention, and the present invention is not limited thereto. All the connection modes improved or transformed from the above description shall fall within the scope of the appended claims of the present invention.

### Embodiment 2

Referring to FIG. 9 to FIG. 11b, a 1*3 surface-mounted RGB LED packaging module according to the present invention has three light emitting units. The structure of the light emitting units is the same as that of the light emitting units in Embodiment 1. As shown in FIGS. 11a and 11b, 24 light emitting units are arranged on the substrate 1 and distributed in 4 rows and 6 columns. As shown in FIG. 11b, the substrate 1 is divided into 8 packaging modules by cutting lines 7, electroplating circuits 6 are also arranged on the positions of the cutting lines 7, and all the electroplating circuits 6 of the present embodiment are arranged on the front side of the substrate 1. All the upper pads 2 are connected to the nearest electroplating circuits 6 at the positions of the cutting lines 7 through the electroplating circuits 6. When the substrate 1 is cut, all the electroplating circuits 6 at the positions of the cutting lines 7 are cut off, and all the upper pads 2 are thus independent from each other and are no longer connected by the electroplating circuits 6.

### Embodiment 3

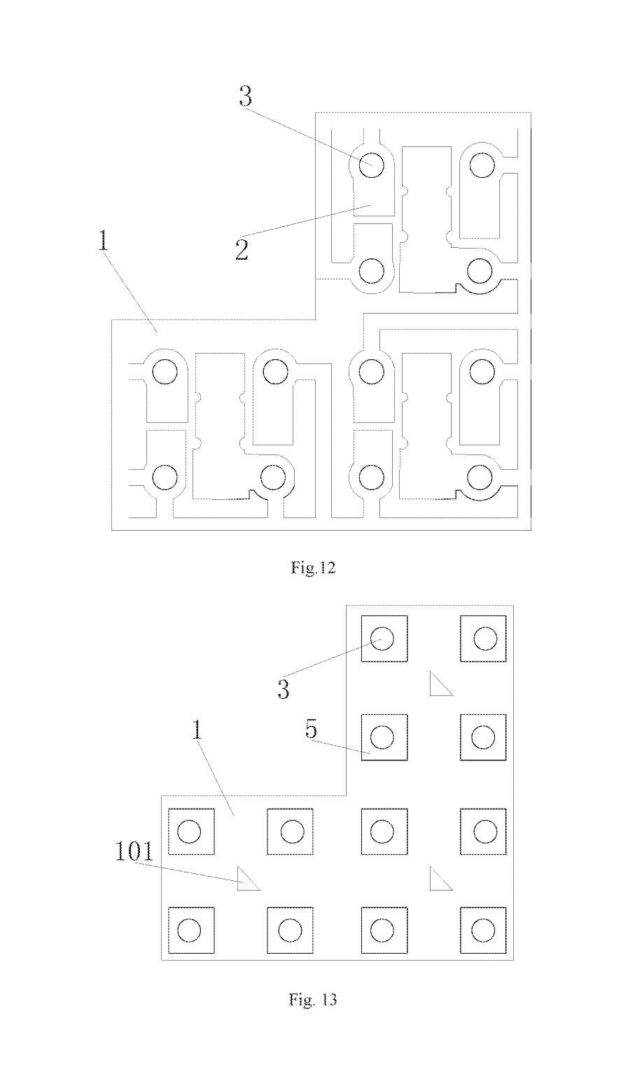

FIG. 12 to FIG. 14 show another 1*3 surface-mounted RGB LED packaging module according to the present invention. All the packaging modules also have three light emitting units, but the arrangement of the light emitting units is different from that in the Embodiment 2. In the present embodiment, the three light emitting units are arranged in an inverted “L” shape, and the arrangement of the light emitting units is not limited in the present invention. As shown in FIG. 14, the electroplating circuits of the present embodiment are arranged on the front side of the substrate 1, the electroplating circuits 6 are also at the positions of the cutting lines 7, all the upper pads 2 are electrically connected to the electroplating circuits 6 at the positions of the cutting lines 7, and the specific connection mode is not limited in the present embodiment.

### Embodiment 4

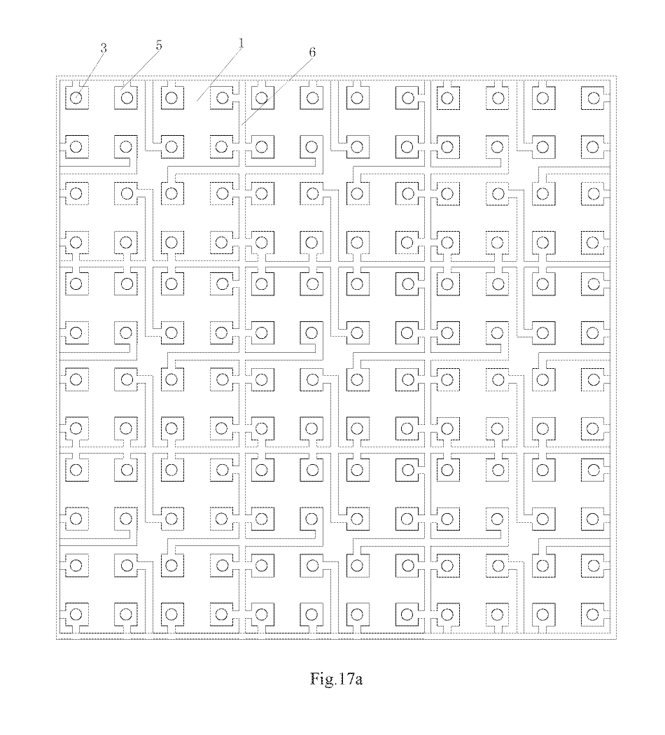

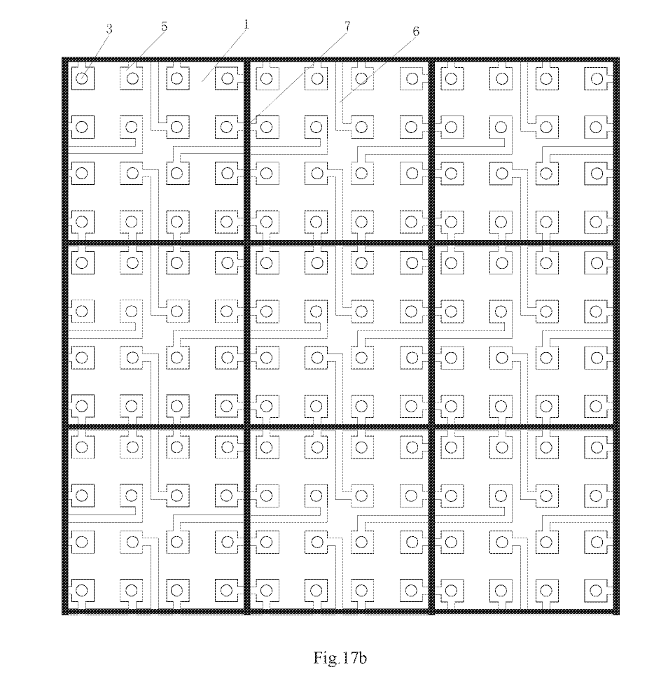

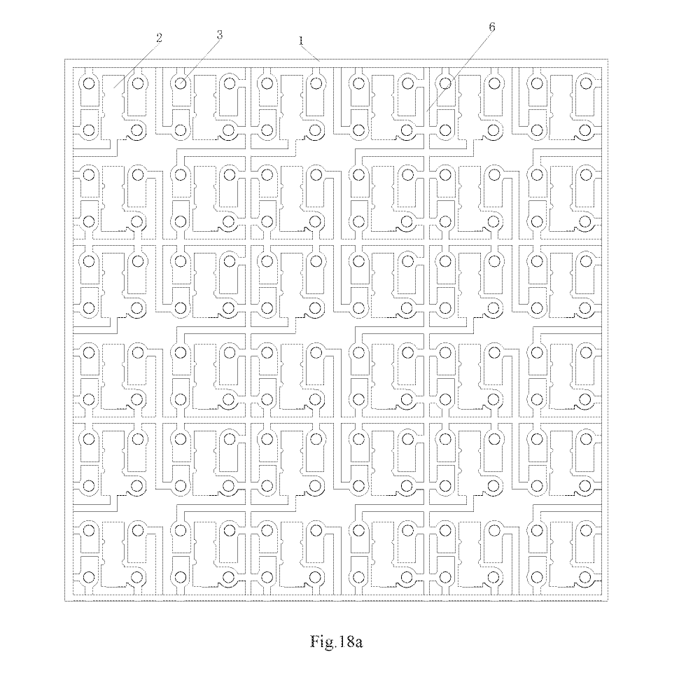

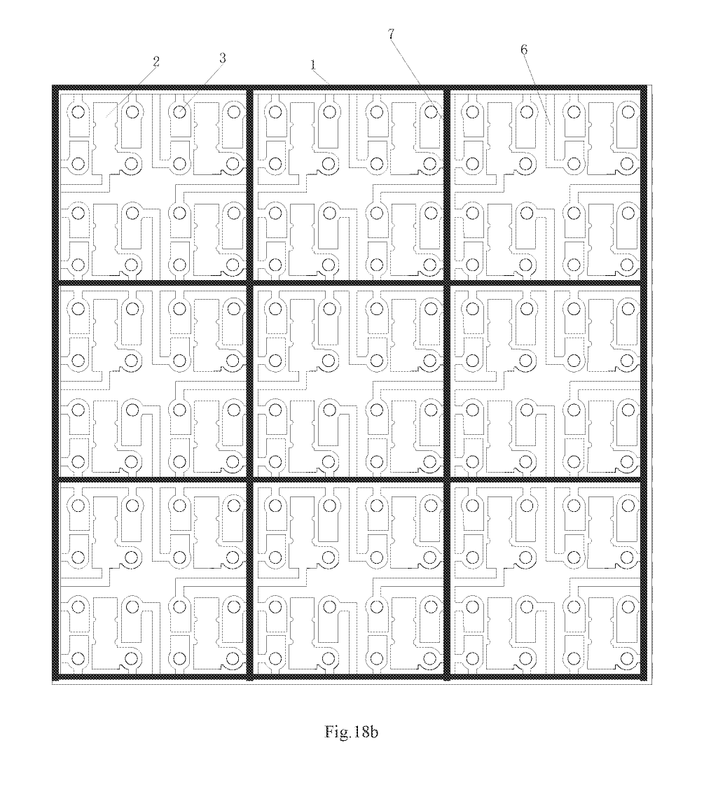

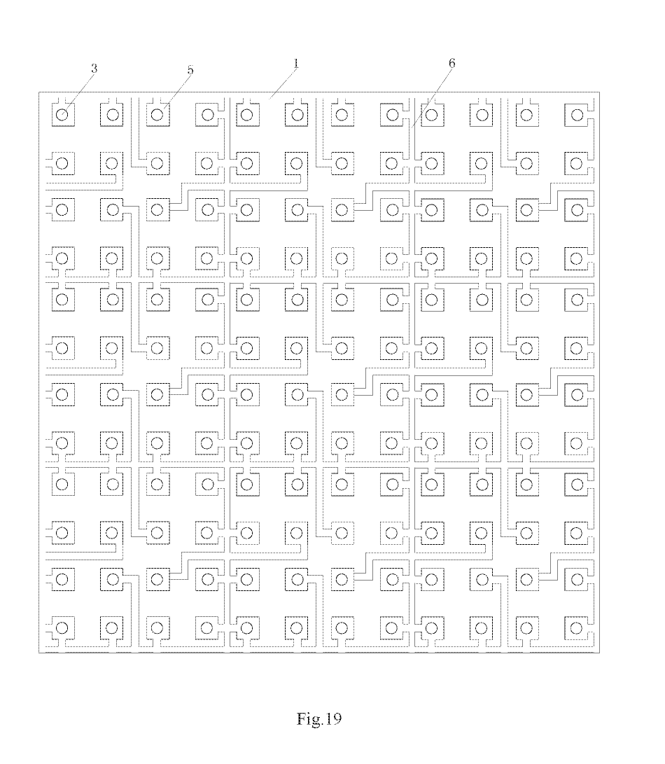

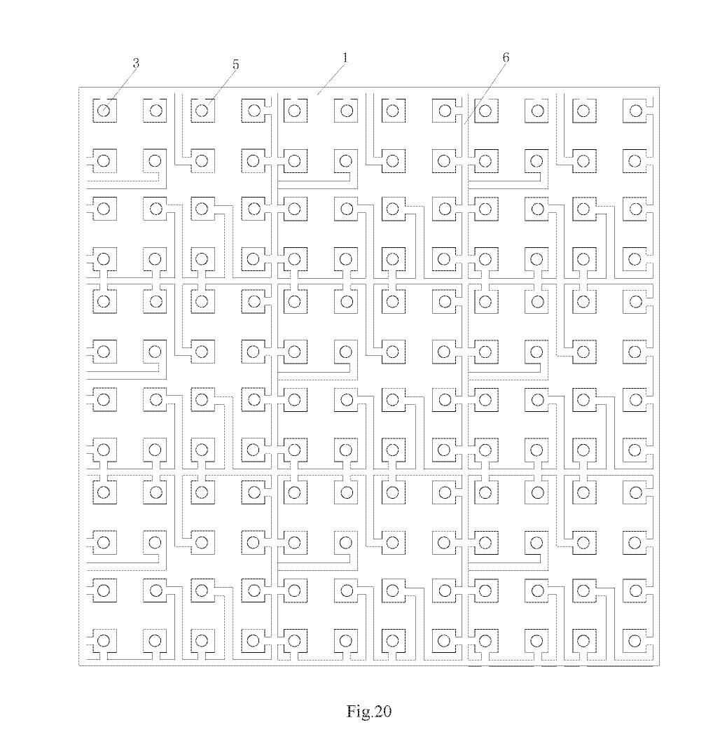

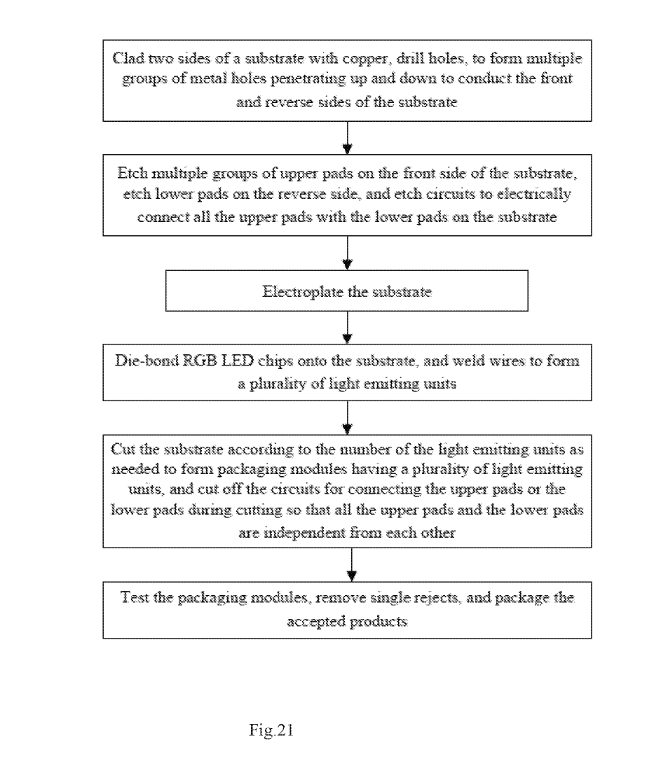

FIGS. 15 to 20 show 1*4 surface-mounted RGB LED packaging modules according to the present invention, wherein the packaging module has four light emitting units. As shown in FIG. 15, the light emitting units are arranged in a square shape, or arranged in a line in other embodiments of the present invention, and the electroplating circuits 6 are connected in the same way as in Embodiments 1 and 2. For the connection mode of the electroplating circuits 6, the electroplating circuits 6 can be arranged on the reverse side of the substrate 1 (as shown in FIG. 17a), or on the front side of the substrate 1 (as shown in FIG. 18a), or on the front and reverse sides. For a specific connection mode, all the pads may be connected to the positions of the cutting lines 7 as in Embodiment 1-3, or as shown in FIG. 19 or FIG. 20. It can be seen that the connection mode of the electroplating circuits 6 is varied, other modifications can be easily obtained by those skilled in the art based on the description of the present invention, and all these improvements and modifications fall within the scope of the appended claims of the present invention.

Referring to FIG. 21, the present invention also provides a preparing method of the surface-mounted RGB LED packaging module, including the following steps:

Step 1: cladding two sides of a substrate 1 with copper, drilling holes, and forming multiple groups of metal holes 3 penetrating up and down to conduct the front and reverse sides of the substrate 1. In practical applications, a BT copper clad plate, an FR4 copper clad plate or other circuit board can be directly used as the substrate 1.

Step 2: etching multiple groups of upper pads 2 on the front side of the substrate 1, etching lower pads 5 on the reverse side, and etching electroplating circuits 6 to electrically connect all the upper pads 2 with the lower pads 5 on the substrate 1. As described above, the electroplating circuits 6 play a role in electrically connecting all the upper pads 2 with the lower pads 5 for electroplating use in subsequent processes, and the connection mode of the electroplating circuits 6 is not limited.

Step 3: electroplating the substrate 1. Preferably, during the electroplating process, the metal holes 3 are filled and sealed to ensure that the glue does not penetrate to the lower pads 5 through the metal holes 3 during the subsequent process of preparing a protective layer 8.

Step 4: die-bonding RGB LED chips 4 onto the substrate 1 by a die-bonding glue, and welding wires to form a plurality of light emitting units. Preferably, physical electrical connection is performed by means of keys and wires.

Step 5: cutting the substrate 1 according to the number of the light emitting units as needed to form packaging modules having a plurality of light emitting units and cutting off the electroplating circuits 6 during cutting so that all the upper pads 2 and the lower pads 5 are independent from each other.

In practical applications, the electroplating circuits 6 are arranged on the front side and/or the reverse side of the substrate 1. Preferably, the electroplating circuits 6 are arranged on the reverse side of the substrate 1 to facilitate cutting.

In a practical application, step 4 further includes: after the light emitting units are formed, preparing the protective layer 8 on the light emitting units.

In a practical application, step 4 further includes: after the light emitting units are formed, preparing an isolating frame 9 around each of the light emitting units. Preferably, the isolating frame 9 is baked and aged to further strengthen the mechanical strength thereof. Preferably, the baking temperature is 100 to 300 degrees Celsius.

The surface-mounted RGB LED packaging module and the preparing method thereof according to the present invention have the advantages that a plurality of light emitting units is integrated into one packaging module, so that the production efficiency of LEDs in subsequent production and application is greatly improved, and the production cost is greatly reduced; at the same time, the plurality of light emitting units is integrated into one module, so compared with the conventional single LED, the LED module provided by the present invention has better sealing performance, and is less susceptible to the erosion of water vapor and longer in service life; and the isolating frame is arranged around the light emitting units to reduce the influence among the light emitting units, thereby improving the resolution and contrast of an LED display screen.

It should be understood that the application of the present invention is not limited to the above examples, modifications or changes may be made by those of ordinary skill in the art according to the above description, and all these modifications and changes shall fall within the scope of the appended claims of the present invention.

1. A surface-mounted RGB-LED packaging module, comprising a substrate and light emitting units arranged on the substrate; a protective layer being arranged on the light emitting units, the number of the light emitting units is at least two, and each light emitting unit comprises four mutually independent upper pads and a group of RGB LED chips; the RGB LED chips are arranged on any one of the upper pads and connected with the other three upper pads by keys and wires; each upper pad is provided with a metal hole that penetrates the substrate and is conductive up and down; lower pads are arranged on the reverse side of the substrate corresponding to the metal holes, and the lower pads are independent from each other.

2. The surface-mounted RGB-LED packaging module according to claim 1, wherein an isolating frame is further arranged around the light emitting units.

3. The surface-mounted RGB-LED packaging module according to claim 2, wherein the isolating frame is a lighttight frame.

4. The surface-mounted RGB-LED packaging module according to claim 1, wherein the surface of the protective layer is rough and non-reflective.

5. A method for preparing the surface-mounted RGB-LED packaging module according to claim 1, comprising the following steps:
step 1: cladding two sides of a substrate with copper, drilling holes, and forming multiple groups of metal holes penetrating up and down to conduct the front and reverse sides of the substrate;
step 2: etching multiple groups of upper pads on the front side of the substrate, etching lower pads on the reverse side, and etching electroplating circuits to electrically connect all the upper pads with the lower pads on the substrate;
step 3: electroplating the substrate;
step 4: die-bonding RGB LED chips onto the substrate, and welding wires to form a plurality of light emitting units; and
step 5: cutting the substrate according to the number of the light emitting units as needed to form packaging modules having a plurality of light emitting units and cutting off the electroplating circuits during cutting so that all the upper pads and the lower pads are independent from each other.

6. The method for preparing the surface-mounted RGB-LED packaging module according to claim 5, wherein the electroplating circuits are arranged on the front side and/or the reverse side of the substrate.

7. The method for preparing the surface-mounted RGB-LED packaging module according to claim 5, wherein step 4 further comprises: after the light emitting units are formed, preparing a protective layer on the light emitting units.

8. The method for preparing the surface-mounted RGB-LED packaging module according to claim 5, wherein step 4 further comprises: after the light emitting units are formed, preparing an isolating frame around each of the light emitting units.

9. The method for preparing the surface-mounted RGB-LED packaging module according to claim 8, wherein the isolating frame is baked at a temperature of 100-300 degrees Celsius for aging.

10. The method for preparing the surface-mounted RGB-LED packaging module according to claim 5, wherein step 3 further comprises filling and sealing the metal holes.
